(19) United States
(12) Patent Application Publication
(10) Pub. No.: US 2009/0324845 A1
(43) Pub. Date: Dec. 31, 2009

(54) METHOD FOR PRODUCING ORIENTATION FILM

(75) Inventors: Yohei Ishida, Honjo-shi (JP); Hirokatsu Miyata, Hadano-shi (JP); Akira Sakai, Kawasaki-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/493,202

(22) Filed: Jun. 28, 2009

(30) Foreign Application Priority Data
Jun. 30, 2008 (JP) 2008-170852

(51) Int. Cl. C23C 14/08

(52) U.S. Cl. 427/529

(57) ABSTRACT

A method for producing an orientation film that causes orientation of a liquid crystal includes a process of vapor depositing an inorganic oxide from an oblique direction on a substrate and forming an obliquely vapor-deposited film composed of a plurality of columnar structural bodies tilted at an angle equal to or greater than 20° from a substrate normal and a process of performing ion beam irradiation onto the plurality of columnar structural bodies constituting the obliquely vapor-deposited film. An ion beam irradiation direction in the ion beam irradiation process is in a plane including a vapor deposition direction of the inorganic oxide and the substrate normal and an angle of the ion beam irradiation direction θ_{IB} measured from the direction of the columnar structural bodies is within a range of +50°≦θ_{IB}≦+100° (θ_{IB} is taken to be positive on a side where the ion beam irradiation direction approaches the substrate normal from the direction of the columnar structural bodies).

### BACKGROUND OF THE INVENTION

1. Field of the Invention

The present invention relates to a method for producing an orientation film that can be applied to a liquid crystal display device. More particularly, the invention relates to a method for producing an inorganic orientation film that can control a pretilt angle of liquid crystal molecules that affects the display performance of a liquid crystal display device.

2. Description of the Related Art

The importance of liquid crystal display devices has greatly increased in recent years. They have been put to use in a variety of fields from displays of cellular phones to PC monitors, television sets, and projectors and now occupy a major position in the field of displays. Accordingly, a large number of research and development projects have recently been aimed at performance improvement and cost reduction of liquid crystal displays.

A basic principle of a liquid crystal display device is well known. The arrangement direction of liquid crystal molecules constituting a liquid crystal layer is changed by applying a voltage to the orderly arranged liquid crystal layer. The polarization state of polarized light passing through the liquid crystal layer is modulated by the difference in the arrangement direction. The ratio of transmitted and absorbed light in a polarizing plate or a phase difference plate located on the light outgoing side varies depending on the state of the modulated polarized light. By controlling the ratio of transmitted and absorbed light with a voltage, brightness can be controlled, thereby enabling the gradation representation.

For a liquid crystal display device to operate based on this principle, the liquid crystal layer has to be arranged orderly. This function is realized by an orientation film. The processing performed in the orientation film includes arranging the liquid crystal molecules in the direction substantially identical to the substrate in-plane direction (azimuth direction).

An organic orientation film such as a polyimide film is typically used as the orientation film, but deterioration of the organic film used under high-intensity light environment such as projectors has recently become a problem. Accordingly, the use of inorganic materials that are high in lightfastness for such applications has expanded.

Some inorganic orientation films are formed by evaporating a starting material under vacuum and irradiating a substrate with an ion beam from an oblique direction. In an inorganic orientation film produced by such an oblique vapor deposition method, the orientation of liquid crystal molecules can be controlled not only in the azimuth direction, but also in the polar angle direction by setting the by appropriately setting the vapor deposition angle. A tilt angle of liquid crystal molecule in the polar angle direction, that is, an angle formed by a liquid crystal molecule with a substrate normal, is called a pretilt angle.

Inorganic orientation films feature a control range of pretilt angle of from 40° to 90° that is wider than that of organic orientation films.

U.S. Pat. No. 5,268,781 discloses an ion beam-assisted oblique vapor deposition method as a method for forming an inorganic orientation film. With this method, unevenness of orientation is reduced by performing ion beam irradiation and oblique vapor deposition at the same time. A similar orientation unevenness reduction effect is also produced when the film obtained by the aforementioned method is used as a base film and oblique vapor deposition is further performed thereupon by turning the vapor deposition orientation through 90°.

In a conventional method combining ion beam assist with oblique vapor deposition, the pretilt angle is controlled within a range of from 0° to 10°, and orientation unevenness can be reduced. Such a pretilt angle is suitable for a VA (Vertical Aligned) mode in which a liquid crystal is oriented at an angle close to that of a perpendicular to a substrate and the tilt angle is controlled by a voltage.

It is also important to control the pretilt angle within a range from a medium angle to a large angle, for example, from an angle equal to or greater than 40° to an angle equal to or less than 80°. Where orientation films of such an angular range are formed in the same direction on the upper and lower substrates and a liquid crystal is introduced therebetween, the orientation such as shown in FIG. 9 or 10 can be obtained. Where the liquid crystals are splay oriented as shown in FIG. 9 and then a voltage is applied to induce a transition from the splay orientation to a bend orientation shown in FIG. 10, it is possible to obtain a liquid crystal element with a high response speed and a high contrast.

However, such a large pretilt angle is difficult to form with good accuracy by the conventional ion beam-assisted vapor deposition method.

### SUMMARY OF THE INVENTION

The present invention has been created to resolve the above-described problems and it provides a method for producing an inorganic orientation film that can control the pretilt angle even in a comparatively large pretilt angle region, for example, within a range of a pretilt angle of equal to or greater than 40° and equal to or less than 80°.

The inventors conducted tests to study how a pretilt angle is related to an inclination angle of columnar structural bodies that form an inorganic orientation film and an ion beam irradiation angle. The obtained results are shown in FIGS. 7A and 7B. These results will be explained below in greater details. The results made it clear that the pretilt angle can be effectively controlled within a large angle range by setting the ion beam irradiation angle within a certain specific range with respect to the growth direction of columnar structural bodies. This finding led to the creation of the present invention.

Thus, the invention provides a method for producing an orientation film that causes orientation of a liquid crystal, including: a process of vapor depositing an inorganic oxide from an oblique direction on a substrate and forming an obliquely vapor-deposited film composed of a plurality of columnar structural bodies tilted in a direction at an angle equal to or greater than 20° from a substrate normal; and a process of performing ion beam irradiation of the plurality of columnar structural bodies constituting the obliquely vapor-deposited film, wherein an ion beam irradiation direction in the ion beam irradiation process is in a plane including a vapor deposition direction of the inorganic oxide and the substrate normal and an angle of the ion beam irradiation direction is within a range of +50°≦θ_{IB}≦+100° (θ_{IB} is measured from the direction of the columnar structural bodies and taken to be positive on a side where the ion beam irradiation direction approaches the substrate normal).

In accordance with the invention, it is possible to provide a method for producing an orientation film that can control the pretilt angle even in a comparatively large pretilt angle region, for example, within a range of a pretilt angle of equal to or greater than 40° and equal to or less than 80°. Where the pretilt angle is controlled using the orientation film in accordance with the invention, it is possible to form stably a liquid crystal oriented state for use in a liquid crystal oriented mode that is particularly advantageous with the use of a large pretilt angle of equal to or greater than 40° and equal to or less than 80°, for example, an OCB mode that is accompanied by a splay-bend transition.

Further features of the present invention will become apparent from the following description of exemplary embodiments with reference to the attached drawings.

### BRIEF DESCRIPTION OF THE DRAWINGS

FIG. 1 is a schematic diagram illustrating an oblique vapor deposition device that is used in the process of forming an obliquely vapor-deposited film in the method for producing an orientation film in accordance with the invention;

FIG. 2 is a schematic diagram illustrating a cross-sectional structure of the obliquely vapor-deposited film in accordance with the invention;

FIG. 3 is a schematic diagram illustrating a cross-sectional structure of a liquid crystal cell;

FIG. 4 is a schematic diagram illustrating an ion beam irradiation device that is used in the ion beam irradiation process in the method for producing an orientation film in accordance with the invention;

FIG. 5 is a process diagram illustrating an example of each process in an embodiment of the invention;

FIG. 6 is a process diagram illustrating an example of each process in an embodiment of the invention;

FIG. 7A is a graph illustrating the relationship between an ion beam irradiation angle and a pretilt angle in the method for producing an orientation film in accordance with the invention;

FIG. 7B is a graph illustrating the relationship between an ion beam irradiation angle and a pretilt angle in the method for producing an orientation film in accordance with the invention;

FIG. 8A illustrates the structure of the orientation film in accordance with the invention that is observed under an electron microscope;

FIG. 8B is a SEM (scanning electron microscopy) photograph illustrating the structure of the orientation film in accordance with the invention that is observed under an electron microscope;

FIG. 9 is a schematic diagram illustrating a splay orientation of a liquid crystal; and

FIG. 10 is a schematic diagram illustrating a bend orientation state of a liquid crystal.

### DESCRIPTION OF THE EMBODIMENTS

An embodiment of the method for producing an orientation film in accordance with the invention will be explained below.

The invention mainly includes the following processes.

Process (a):

An obliquely vapor-deposited film formation process of vapor depositing an inorganic oxide by an oblique vapor deposition method on a substrate and producing an obliquely vapor-deposited film composed of a plurality of columnar structural bodies tilted in substantially the same direction.

Process (b):

An ion beam irradiation process of irradiating the plurality of columnar structural bodies constituting the obliquely vapor-deposited film with an ion beam at a specific angle.

These processes will be described below in greater details.

Process (a): Obliquely Vapor-Deposited Film Formation Process

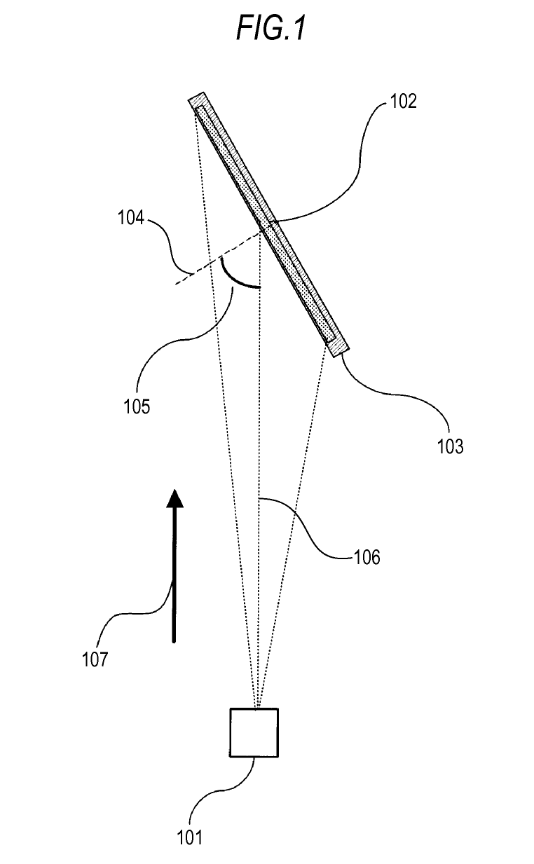

FIG. 1 is a schematic diagram illustrating an oblique vapor deposition device that is used in the process of forming an obliquely vapor-deposited film in the method for producing an orientation film in accordance with the invention. In FIG. 1, the reference numeral 101 stands for a vapor deposition source, 102—a substrate, 103—a substrate holder, 104—a substrate normal, 105—a vapor deposition angle, 106—a vapor deposition distance, and 107—a vapor deposition direction. The oblique vapor deposition device shown in FIG. 1 is disposed in a vacuum apparatus.

A material that will constitute the obliquely vapor-deposited film is introduced as a starting material for vapor deposition in the vapor deposition source 101, the starting material for vapor deposition is heated by an appropriate method such as a resistance heating method or electron beam vapor deposition method, vapor deposition is performed on the substrate 102, and the obliquely vapor-deposited film is formed.

Any material may be used as the starting material for vapor deposition, provided that the orientation film that will be formed will cause the liquid crystals to be arranged at a predetermined azimuth angle. Specific examples of suitable materials include silicon oxides (SiOₓ: x is about 1-2) such as silicon dioxide (SiO₂) and silicon monoxide (SiO), magnesium oxide (MgO), aluminum oxide (Al₂O₃), zinc oxide (ZnO), titanium oxide (TiO₂), zirconium oxide (ZrO₂), chromium oxide (Cr₂O₃), cobalt oxide (Co₃O₄), iron oxide (Fe₂O₃, Fe₃O₄), magnesium fluoride (MgF₂), silicon nitrides (SiNₓ), and aluminum nitride (AlN).

However, in order to demonstrate the sufficient effect of the invention, silicon oxides (SiOₓ) such as silicon dioxide (SiO₂) and silicon monoxide (SiO) are preferred. With these materials, the liquid crystal orientation state can be controlled by the conditions under which the material film is formed.

The starting material for vapor deposition can be advantageously used in the form of a power, granules, pellets, and the like, but the shape and size thereof are not limited, provided that liquid crystal orientation can be controlled.

The substrate holder 103 is used to hold the substrate 102. The vapor deposition angle 105 is set by moving the substrate holder 103.

In accordance with the invention, the vapor deposition angle 105 indicates an angle formed by the substrate normal 104 and a segment (corresponds to the vapor deposition distance 106 in FIG. 1) connecting the centers of the vapor deposition source 101 and the substrate 102. The vapor deposition angle 105 differs depending on the device configuration, but usually can be set between 0° and 90°. In a case where an obliquely vapor-deposited film is produced that will be used as an orientation film for use in a liquid crystal element, the vapor deposition angle is usually set within a range of from 50° to 90°. By setting the vapor deposition angle 105 within this range, it is possible to impart anisotropy caused by the vapor deposition direction 107 to the obliquely vapor-deposited film for obtaining liquid crystal molecules oriented unidirectionally.

In accordance with the invention, in the process of forming the obliquely vapor-deposited film, it is preferred that the angle formed by the vapor deposition direction of the inorganic oxide with the substrate normal be equal to or greater than 60° and less than 90°, that is, that the vapor deposition angle be set within a range of equal to or greater than 60° and less than 90°. By setting the vapor deposition angle within this range, it is possible to control the pretilt angle in the ion beam irradiation process performed in the below-described process (b) within a range of equal or greater than 40° and equal to or less than 80°.

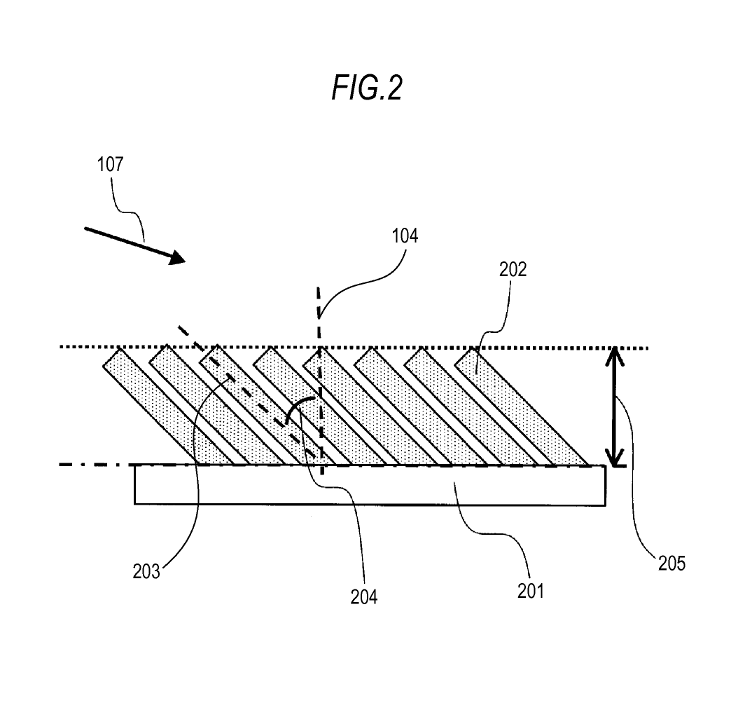

FIG. 2 is a schematic diagram illustrating a cross-sectional structure of the obliquely vapor-deposited film in accordance with the invention. In FIG. 2, the reference numeral 201 stands for a substrate, 202—a columnar structural body, 203—a growth direction of the columnar structure body, 204—an inclination angle θ_{c} of the columnar structural body, and 205—a film thickness.

The obliquely vapor-deposited film formed on the surface of the substrate 201 has a cross-sectional structure shown in FIG. 2. The vapor deposition direction 107 shown in FIG. 1 corresponds to the vapor deposition direction 107 shown in FIG. 2. An electrode such as a transparent electrode and a reflective electrode is formed on the substrate 201 for applying a voltage and driving the liquid crystal display element.

Furthermore, in accordance with the invention, it is desirable that the inclination angle θ_{c} 204 of the columnar structural body constituting the obliquely vapor-deposited film be equal to or greater than 20°, more preferably equal to or greater than 20° and equal to or less than 50°. Where the inclination angle of the columnar structural body of the obliquely vapor-deposited film produced by the oblique vapor deposition method is equal to or greater than 20°, the pretilt angle is equal to or less than 70° and the pretilt angle control in the below-described ion beam irradiation process can be effectively performed.

The thickness 205 of the obliquely vapor-deposited film is preferably equal to or greater than 10 nm, more preferably equal to or greater than 10 nm and equal to or less than 500 nm. Where the film thickness is equal to or greater than 10 nm, a high pretilt angle of equal to or less than 70° can be demonstrated, while maintaining the same orientation of azimuth direction. This pretilt angle range can be advantageously controlled in the below-described ion beam irradiation process. The film thickness can be set by a vapor deposition time.

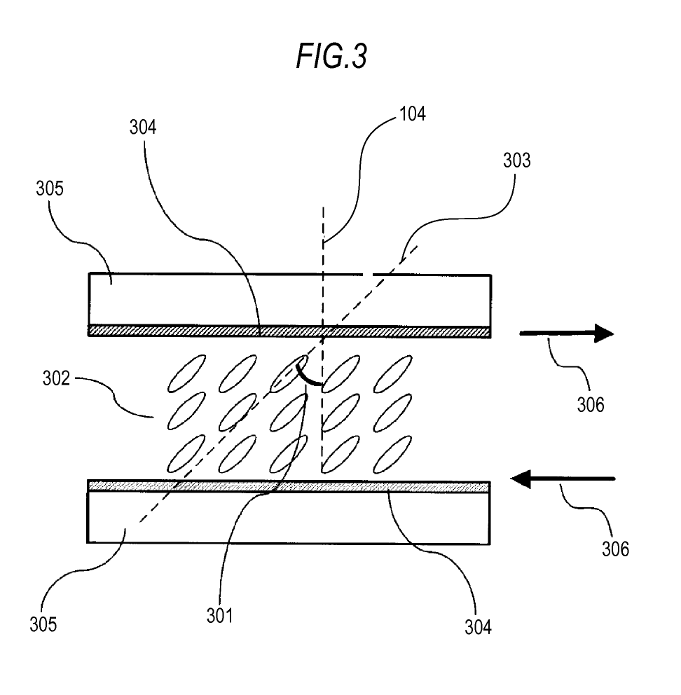

A pretilt angle of liquid crystal molecules that is demonstrated by the inorganic orientation film will be described below. FIG. 3 is a schematic drawing illustrating a cross-sectional structure of a liquid crystal cell. In FIG. 3, the reference numeral 301 stands for a pretilt angle θₚ, 302—a liquid crystal molecule, 303—a liquid crystal orientation direction, 304—an orientation film, 305—a glass substrate, and 306—an orientation treatment direction. The orientation treatment as referred to herein is a treatment performed for orienting liquid crystal molecules in a specific direction, for example, rubbing, oblique vapor deposition, and ion beam irradiation. The orientation treatment direction is a direction in which the orientation treatment is performed. For example, in case of rubbing, this is the rubbing roller rotation direction, and in case of oblique vapor deposition, this is a vapor deposition direction. In accordance with the invention, the pretilt angle θₚ 301 in a case where the obliquely vapor-deposited film is used as the orientation film of a liquid crystal element is defined as an angle formed by a liquid crystal element 602 and the substrate normal. The pretilt angle θₚ 301 can be measured by a crystal rotation method, a magnetic field threshold method, conoscope observations, and the like.

Process (b): Ion Beam Irradiation Process

A process of irradiating the obliquely vapor-deposited film produced in the process (a) with an ion beam from a fixed direction will be described below.

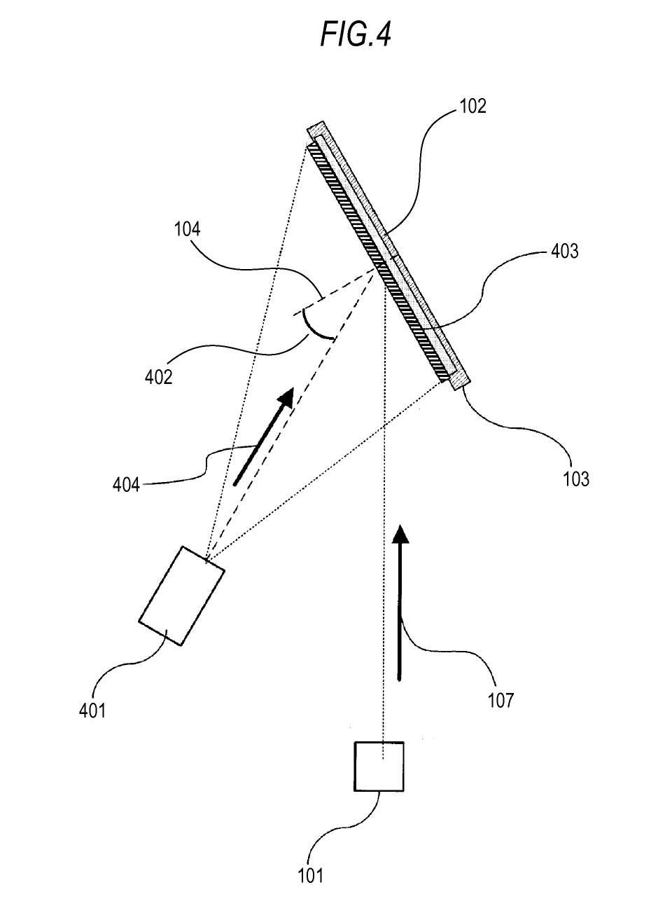

FIG. 4 is a schematic diagram illustrating an ion beam irradiation device that is used in the ion beam irradiation process in the method for producing an orientation film in accordance with the invention. In FIG. 4, the reference numeral 401 stands for an ion source, 402—an ion beam irradiation angle, 403—an obliquely vapor-deposited film, and 404—an ion beam irradiation direction.

In accordance with the invention, an ion beam is generated by using the ion source 401 and introducing a gas including ion species for irradiation, and the substrate is irradiated with the generated ion beam at a fixed angle. The fixed angle as referred to herein is the ion beam irradiation angle 402 in FIG. 4. In accordance with the invention, this angle is set correspondingly to the inclination angle 204 of the columnar structural body shown in FIG. 2.

The irradiation direction 404 of the ion beam in the process of irradiation with the ion beam is set within a plane including the substrate normal 104 and the vapor deposition direction 107 in the oblique vapor deposition method. Thus, the direction in which the columnar structural body 202 is tilted as shown in FIG. 2, the ion beam irradiation direction 404, and the substrate normal 104 are located within the same plane. Where ion beam irradiation is performed from this direction, the pretilt angle can be controlled, while maintaining the liquid crystal orientation ability in the azimuth direction of the inorganic orientation film.

The ion beam irradiation method will be explained below.

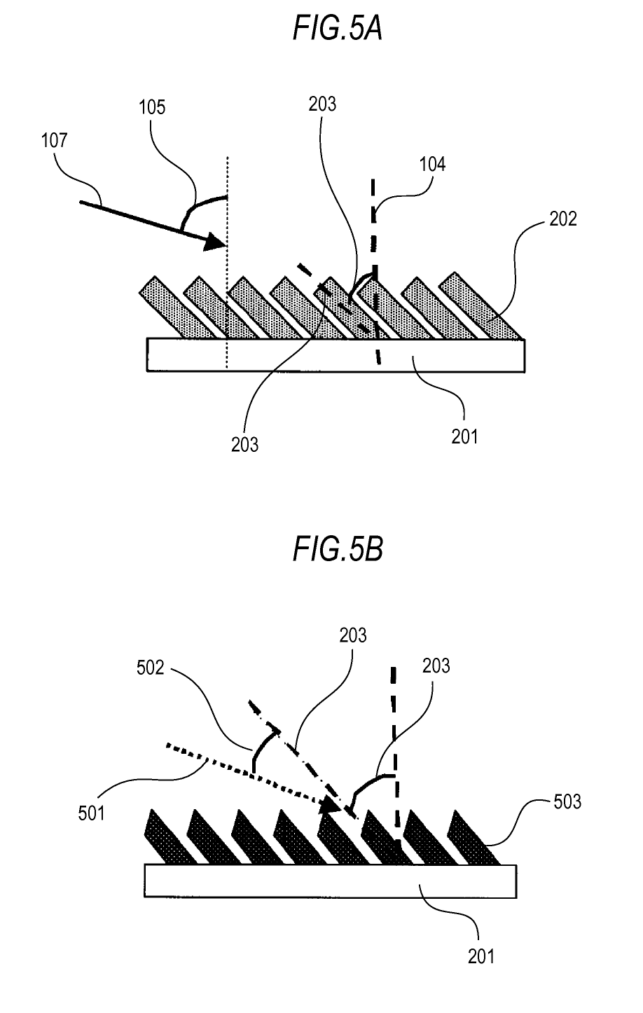

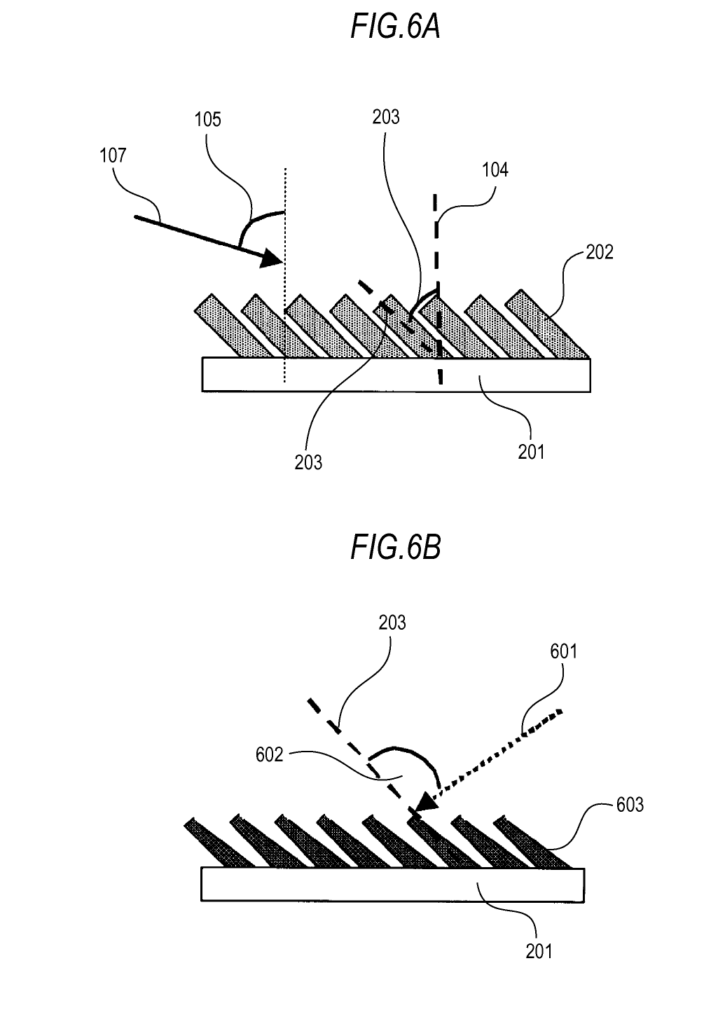

The ion beam irradiation direction in accordance with the invention is established with reference to the growth direction of columnar structural bodies, as explained in FIG. 5 and FIG. 6. As for the inclination angle θ_{c} of the columnar structural bodies and ion beam irradiation direction required to control effectively the pretilt angle by ion beam irradiation, it is preferred that the following condition be satisfied with reference to the growth direction of columnar structural bodies: +50°≦θ_{IB}≦+100°, where θ_{IB} stands for an ion beam irradiation angle formed by the growth direction of the columnar structural bodies and ion beam irradiation direction.

The angle θ_{IB}=0° is an angle at which the growth direction of the columnar structural bodies and ion beam irradiation direction are identical. θ_{IB} is taken to be positive on a side where the ion beam irradiation direction approaches the substrate normal from the inclination angle of the columnar structural bodies. θ_{IB} is negative when the ion beam irradiation direction is inclined with respect to the direction of the inclination angle θ_{c} of the columnar structural bodies and when the angle formed by the ion beam irradiation direction and the substrate normal is larger than θ_{c}. θ_{IB} is positive when the ion beam irradiation direction is inclined with respect to the direction of the inclination angle θ_{c} of the columnar structural bodies and when the angle formed by the ion beam irradiation direction and the substrate normal is less than θ_{c}, or when the ion beam irradiation direction is inclined in the direction opposite that of the inclination angle θ_{c} of the columnar structural bodies.

By setting to the above-described irradiation angle, the pretilt angle variation amount is increased and, therefore, pretilt angle controllability is increased by comparison with those in a case where an irradiation angle outside the aforementioned range is selected. FIG. 5 serves to illustrate a case in which the ion beam irradiation angle is negative; the ion beam irradiation method shown in this figure is outside the application range of the invention.

FIG. 5A illustrates a method for forming an obliquely vapor-deposited film.

The vapor deposition angle 105 is set so that the inclination angle θ_{c} 203 of columnar structural bodies after the columnar structural bodies 202 have been formed to the substrate 201 becomes a predetermined angle, and the obliquely vapor-deposited film is formed by vapor deposition from the vapor deposition direction 107.

Then, as shown in the process illustrated by FIG. 5B, irradiation with ion beam is performed in an arrangement similar to that of the process illustrated by FIG. 5A, in the direction identical to the vapor deposition direction 107 of oblique vapor deposition, and so that an angle formed by the ion beam irradiation direction 1: 501 and the substrate normal 104 is larger than the vapor deposition angle 105. The sign of ion beam irradiation angle θ_{IB} 502 at this time is (−Thus, the negative (−) sign of the ion beam irradiation angle θ_{IB} 502 means that the ion beam irradiation direction is inclined with respect to the direction of the inclination angle θ_{c} of the columnar structural bodies and that ion beam irradiation is performed from an angle below the growth direction 203 of the columnar structural bodies.

An ion beam irradiation method shown in FIG. 6 will be explained below.

The process shown in FIG. 6A is identical to the oblique vapor-deposited film formation process illustrated by the FIG. 5A. Then, irradiation with ion beam is performed from the ion beam irradiation direction 2: 601, as shown in FIG. 6B. In this case, an ion beam irradiation angle θ_{IB} 602 is positive (+). A case in which the ion beam irradiation angle is negative (−) is explained using FIG. 5B. By contrast, FIG. 6B illustrates a positive (+) angle. As shown in FIG. 6B, the case in which the ion beam irradiation angle is positive (+) is a case in which he ion beam irradiation direction is inclined with respect to the direction of the inclination angle θ_{c} of the columnar structural bodies at an angle below the growth direction 203 of the columnar structural bodies and a case in which ion beam irradiation direction is inclined in the direction opposite that of the direction of the inclination angle θ_{c} of the columnar structural bodies.

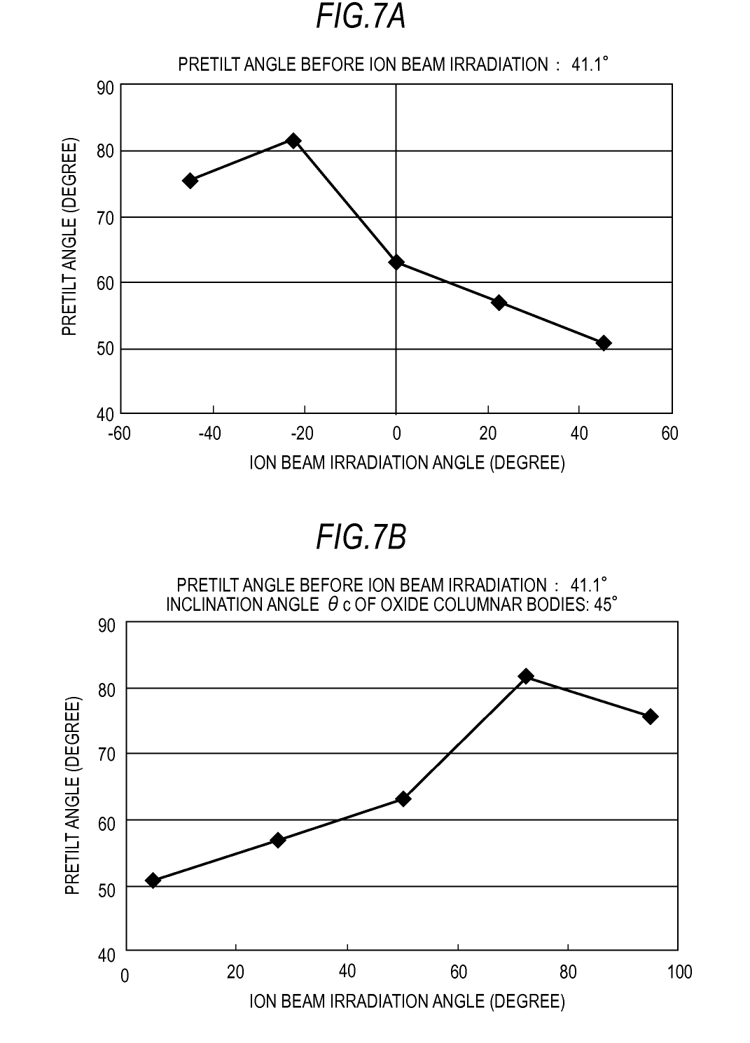

FIGS. 7A and 7B are graphs illustrating the relationship between the ion beam irradiation angel and the pretilt angle.

FIGS. 7A and 7B represent the same data by using different abscissas. The ion beam irradiation angle on the abscissa shown in FIG. 7A shows the ion beam irradiation angle 402 in FIG. 4, whereas the ion beam irradiation angle on the abscissa shown in FIG. 7B shows the ion beam irradiation angles θ_{IB} 502, 602 shown in FIGS. 5 and 6.

The results shown in FIG. 7 indicate that a pretilt angle variation differs depending on irradiation angle when the columnar structural bodies are irradiated with an ion beam.

The pretilt angle measured using an inorganic orientation film prior to ion beam irradiation is 41.1°, but the pretilt angle has been confirmed to vary when ion beam irradiation is performed at an ion beam irradiation angle within the above-described range. In particular, a large variation amount of equal to or more than 20° of the pretilt angle is observed when the ion beam irradiation angle θ_{IB} is within a range of +50°≦θ_{IB}≦+100°.

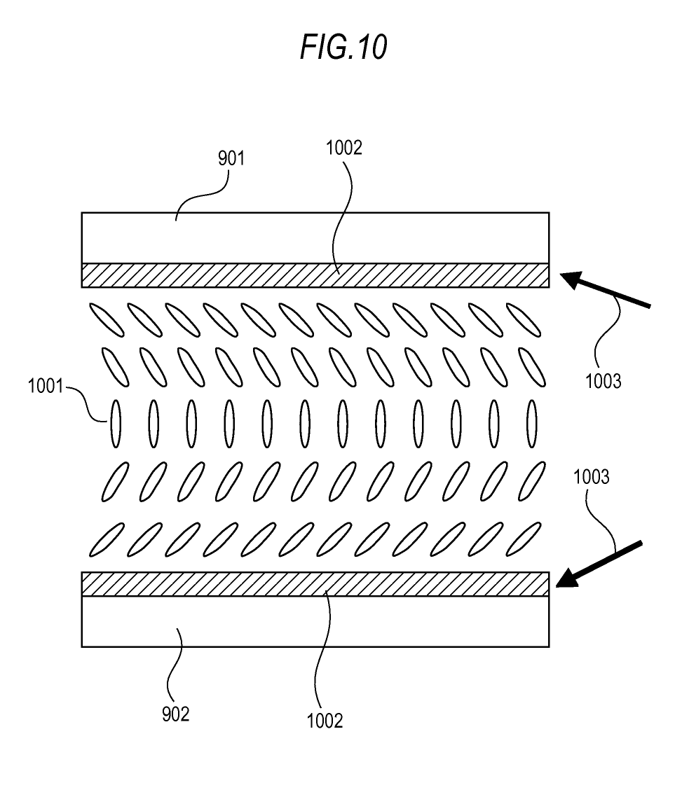

The bend orientation shown in FIG. 10 is demonstrated at a pretilt angle of equal to or greater than 45°, but in order to obtain a high-contrast bend orientation, the pretilt angle has to be further increased, and it is preferred that ion beam irradiation be performed at an angle in the above-described range.

The results shown in FIG. 7 demonstrate that where the ion beam irradiation angle θ_{IB} becomes larger than 70°, the pretilt angle conversely decreases. Therefore, a more preferred range for controlling the pretilt angle is +50°≦θ_{IB}≦+70°.

Ions that are the main components of the ion beam emitted from the ion source 201 shown in FIG. 4 are ion species such that enable, as a result of irradiation therewith, the control of the pretilt angle of the obliquely vapor-deposited film 403. In particular, argon ions are the preferred ion species that demonstrate the target effect of the invention. However, the invention is not limited to argon ions and it goes without saying that where other ion species are more effective for the pretilt angle control, it would be preferred to conduct ion beam irradiation by using such ions.

### EXAMPLE 1

In the present example, an inorganic orientation film is provided by producing an obliquely vapor-deposited film with a thickness of 300 nm at a vapor deposition angle of 87.5° as the first process and then performing ion beam irradiation from the direction opposite the vapor deposition direction of oblique vapor deposition, that is from the direction opposite the inclination direction of silicon oxide (SiOₓ) columnar structural bodies (direction shown in FIG. 6) at an angle of +62.5° from the columnar structural body growth direction.

Process (a): Obliquely Vapor-Deposited Film Formation Process

First, an obliquely vapor-deposited film is formed by an oblique vapor deposition method on a substrate having electrodes formed thereon. The oblique vapor deposition device shown in FIG. 1 is used for oblique vapor deposition. The substrate 102 is disposed at the substrate holder 103 and the substrate holder 103 is inclined so as to obtain the vapor deposition angle 105 (shown in FIG. 1) of 87.5°. The vapor deposition distance 106 in this case is 100 cm.

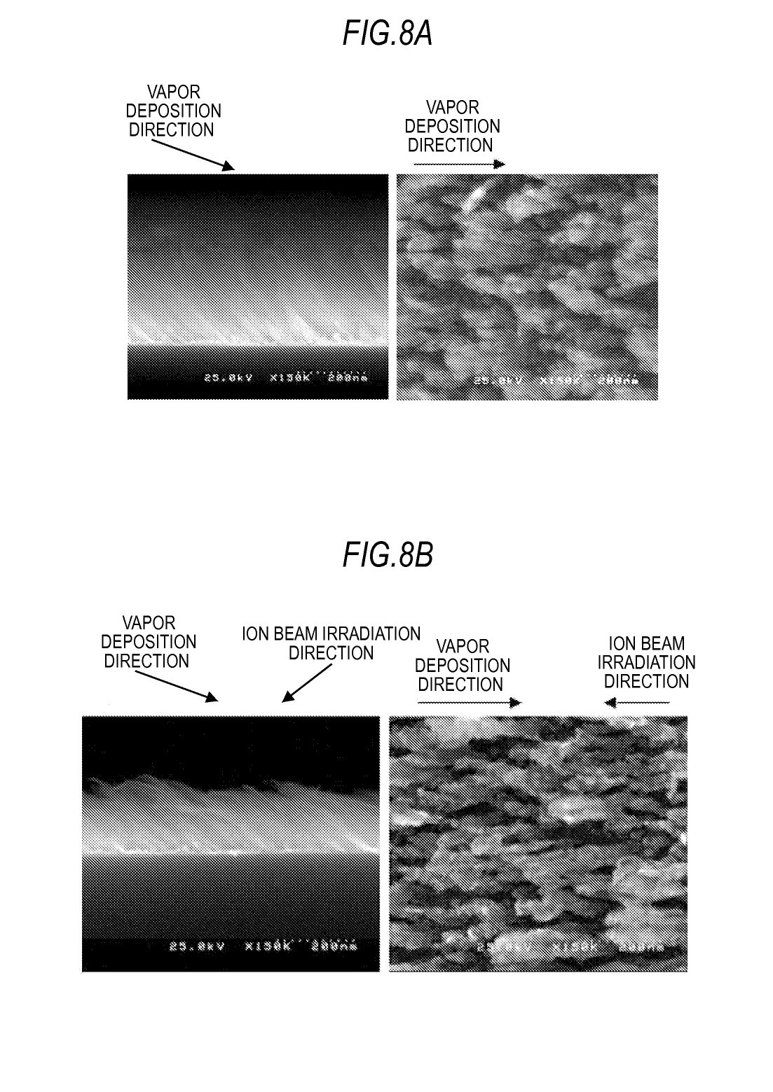

Vapor deposition is then started and the obliquely vapor-deposited film with a thickness of 300 nm is produced. The cross-sectional structure of the obliquely vapor-deposited film is observed using a SEM (scanning electron microscope; S-5000H, manufactured by Hitachi High-Technology Co., Ltd.). Structural bodies shown in the SEM (scanning electron microscope) photograph shown in FIG. 8A are observed. The obliquely vapor-deposited film in the present example has a thickness of 300 nm and is constituted by a plurality of columnar structural bodies that are inclined at an inclination angle within a range of from 45° to 55° and have an average inclination angle of 50°. The SEM photograph shown on the left side in FIG. 8A shows a cross-sectional structure of the obliquely vapor-deposited film, and the SEM photograph shown on the right side in FIG. 8A shows a surface structure of the obliquely vapor-deposited film.

In order to measure the pretilt angle of the obliquely vapor-deposited film prior to ion beam irradiation, a transmission liquid crystal cell is produced by forming an inorganic orientation film on a glass substrate by the same production method and disposing the substrates so that the orientation directions of the opposing inorganic orientation films are antiparallel. The liquid crystal cell in this case has an orientation state such as shown in FIG. 3. A liquid crystal mixture MLC-2050 (manufactured by Merck Co.) is injected into the liquid crystal cell and the pretilt angle is measured by a crystal rotation method. The resultant pretilt angle is 41.9°.

A transmission type liquid crystal cell is produced by similarly forming an obliquely vapor deposited film by using glass substrates provided with transparent electrodes and disposing the substrates so that the orientation directions of the opposing inorganic orientation films are parallel. The cell thickness in this case is 3 μm. By disposing the cell between polarizing plates with a cross Nicol arrangement so that the orientation treatment direction is at an angle of 45° with respect to the polarization axes of the polarizing plates and performing observations, it is possible to confirm that the liquid crystal cell is of a blackish gray color when no voltage is applied.

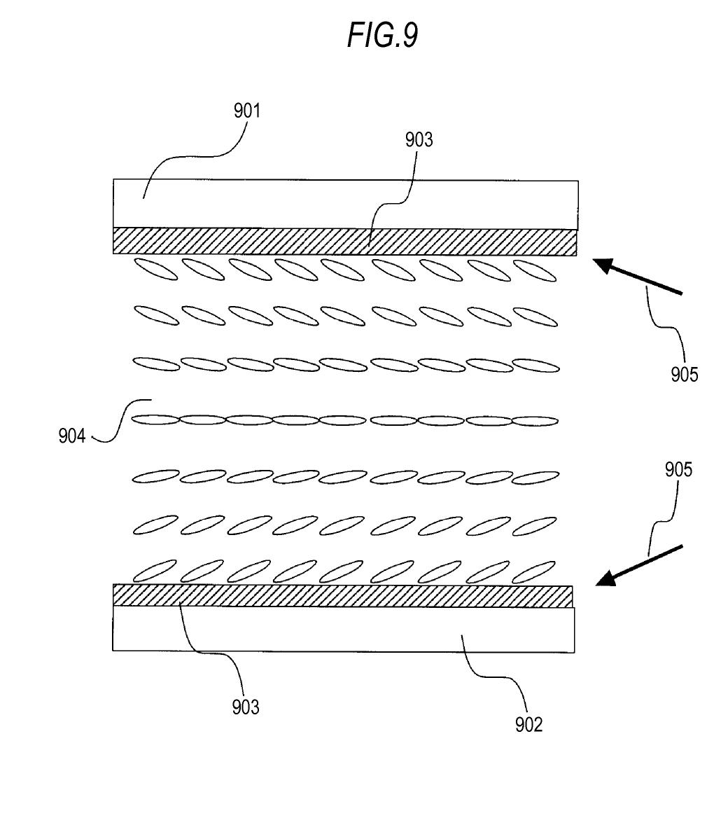

In a cell with a pretilt angle larger than 50°, a splay orientation state shown in FIG. 9 is assumed when no voltage is applied and a yellowish color appears under a polarization microscope. By contrast, in the bend orientation state shown in FIG. 10, the color is gray. In the cell with a pretilt angle of 41.9° in the present embodiment, the liquid crystal orientation state inside the cell when no voltage is applied becomes a bend orientation.

Process (b): Ion Beam Irradiation Process

The obliquely vapor deposited film produced in the process (a) is irradiated with an ion beam by using the configuration shown in FIG. 4. The ion source 401 is an ion source of an end hole type (manufactured by Veeco Co.). In the present embodiment, irradiation is performed with an argon ion beam. The ion beam irradiation angle is set, as shown in FIG. 6, so that the angle θ_{IB} shown in FIG. 8 is an angle of +62.5° from the direction opposite that of oblique vapor deposition in process (a), where the inclination direction (50°) of columnar structural bodies obtained by SEM (scanning electron microscopy) observations in process (a) is taken as a reference, that is, as 0°.

The irradiation conditions are set to a cathode voltage of 200 V and a cathode current of 5 A. The ion source shutter is opened when the ion beam emission is stable and ion beam irradiation is started. The irradiation time is 5 min.

The structure of the inorganic orientation film before and after ion beam irradiation is observed using SEM (scanning electron microscopy). A structure shown in the SEM (scanning electron microscopy) photograph shown in FIG. 8B is observed. The results of SEM observations confirm structural changes in the columnar structural bodies that are caused by ion beam irradiation. Furthermore, the SEM photograph on the left side of FIG. 8B shows a cross-sectional structure of the obliquely vapor deposited film, and the SEM photograph on the right side of FIG. 8B shows a surface structure of the obliquely vapor deposited film.

A transmission-type liquid crystal cell of an antiparallel arrangement for pretilt angle confirmation is produced by using the obliquely vapor deposited film subjected to ion beam irradiation. The production method is similar to that used in process (a). The pretilt angle of this liquid crystal cell is confirmed to be 62.0° and a pretilt angle increase of 20.1° over that before ion beam irradiation can be confirmed.

A transmission-type liquid crystal cell of a parallel arrangement for pretilt angle confirmation is produced by using the obliquely vapor deposited film subjected to ion beam irradiation. The cell thickness is 3 μm. Where the liquid crystal cell is then arranged between polarizing plates of cross Nicol arrangement and observations are performed, the liquid crystal cell is found to be yellow in a state without voltage application. This result indicates that the liquid crystal orientation inside the cell is in a splay orientation state.

Where a voltage is gradually applied in this state, a gray region indicating a bend orientation appears in the yellow region inside the cell when a voltage of 2 V is applied. Where the voltage is further applied, the region expands and eventually the entire surface can be confirmed to be gray. This result indicates that voltage application causes a transition in the orientation state from the splay orientation state (state shown in FIG. 9) to a bend orientation state (state shown in FIG. 10).

This result confirms that where ion beam irradiation of process (b) is performed, the pretilt angle of the obliquely vapor deposited film that has a pretilt angle of 41.9° increases to 62°, and the orientation state of the parallel orientation cell in a state without voltage application changes accordingly from bend orientation to splay orientation.

### EXAMPLE 2

In the present example, an inorganic orientation film is produced by a method similar to that of Example 1, except that the vapor deposition angle in process (a) of Example 1 is 85° and the thickness of the obliquely vapor deposited film is 80 nm.

The pretilt angle prior to ion beam irradiation is measured by the same method as used in Example 1. The result is 52°. SEM (scanning electron microscopy) observations are performed according to the same procedure as in Example 1. The inclination angle of columnar structural bodies is 40°.

The ion beam irradiation angle is then set to +62.5° with respect to the growth direction of the columnar structural bodies as a reference, in the same manner as in Example 1, and ion beam irradiation is performed, other irradiation conditions being similar to those of Example 1. As a result, the pretilt angle becomes 70°, and the pretilt angle is changed by performing ion beam irradiation, at a predetermined angle, of columnar structural bodies of the obliquely vapor deposited film produced under the above-described conditions.

### EXAMPLE 3

In the present example the conditions of process (a) are set to obtain a vapor deposition angle of 80° and a film thickness of 50 nm, ion beam irradiation is performed by a method similar to that of Example 1 in process (b), and an inorganic orientation film is produced.

Under the conditions of the present example, the pretilt angle after completion of process (a) becomes 55° and the inclination angle of columnar structural bodies determined by SEM (scanning electron microscopy) observations is 38°. The pretilt angle after completion of process (b) is 71°.

### COMPARATIVE EXAMPLE 1

In the present comparative example, an inorganic orientation film is produced by a manufacturing method similar to that of Example 3, except that the vapor deposition angle during oblique vapor deposition is set to 60° and the film thickness is set to 50 nm.

Structural observations conducted by SEM (scanning electron microscopy) demonstrate that under the production conditions of the present comparative example, the inclination angle of the columnar structural bodies is 15°.

Liquid crystal orientation after the obliquely vapor deposited film has been formed in process (a) is formed to be random and the pretilt angle cannot be measured.

A similar result is also obtained when the pretilt angle is measured via process (b), and it is clear that with the method of the present comparative example, the liquid crystal molecules are not oriented in the same direction.

The above-described results indicate that where an inorganic orientation film is produced under the conditions of the present comparative example, the inclination angle of the columnar structural bodies becomes less than 20° and a film with a stable unidirectional orientation of liquid crystals after ion beam irradiation cannot be formed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-170852, filed Jun. 30, 2008, which is hereby incorporated by reference herein in its entirety.

What is claimed is:

1. A method for producing an orientation film that causes orientation of a liquid crystal, comprising:
a process of vapor depositing an inorganic oxide from an oblique direction on a substrate and forming an obliquely vapor-deposited film composed of a plurality of columnar structural bodies tilted at an angle equal to or greater than 20° from a substrate normal; and
a process of performing ion beam irradiation onto the plurality of columnar structural bodies constituting the obliquely vapor-deposited film; wherein
an ion beam irradiation direction in the ion beam irradiation process is in a plane including a vapor deposition direction of the inorganic oxide and the substrate normal and an angle of the ion beam irradiation direction θ_{IB} measured from the direction of the columnar structural bodies is within a range of +50°≦θ_{IB}≦+100° (θ_{IB} is taken to be positive on a side where the ion beam irradiation direction approaches the substrate normal from the direction of the columnar structural bodies).

2. The method for producing an orientation film according to claim 1, wherein in the process of producing the obliquely vapor-deposited film, the angle of the vapor deposition direction measured from the substrate normal is equal to or greater than 60° and less than 90°.

3. The method for producing an orientation film according to claim 1, wherein a thickness of the obliquely vapor-deposited film is equal to or greater than 10 nm.

4. The method for producing an orientation film according to claim 1, wherein the angle of the ion beam irradiation direction θ_{IB} is within a range of +50°≦θ_{IB}≦+70°.

5. The method for producing an orientation film according to claim 1, wherein the ion beam irradiation direction is opposite to the vapor deposition direction of the inorganic oxide, with respect to the substrate normal, in the process of forming the obliquely vapor-deposited film.

6. The method for producing an orientation film according to claim 1, wherein the ion beam includes argon ions as the main component.
